(19) United States
(12) Patent Application Publication
(10) Pub. No.: US 2024/0266425 A1
(43) Pub. Date: Aug. 8, 2024

(54) HEMT TRANSISTOR

(71) Applicant: STMicroelectronics International N.V., Geneva (CH)

(72) Inventors: Aurore CONSTANT, Tours (FR); Ferdinando IUCOLANO, Gravina di Catania (IT); Cristina TRINGALI, Augusta (IT); Maria Eloisa CASTAGNA, Catania (IT)

(73) Assignee: STMicroelectronics International N.V., Geneva (CH)

(21) Appl. No.: 18/422,867

(22) Filed: Jan. 25, 2024

(30) Foreign Application Priority Data
Feb. 6, 2023 (FR) 2301105

(51) Int. Cl. H01L 29/778; H01L 29/66

(52) U.S. Cl. CPC H01L 29/778; H01L 29/66462

(57) ABSTRACT

The present disclosure relates to a method of forming an HEMT transistor, comprising the following successive steps: a) providing a stack comprising a semiconductor channel layer, a semiconductor barrier layer on top of and in contact with the semiconductor channel layer, and a semiconductor gate layer arranged on top of and in contact with the semiconductor barrier layer, the semiconductor gate layer comprising P-type dopant elements; and b) compensating for the P-type doping with oxygen atoms, in an upper portion of the semiconductor gate layer, by an oxygen anneal, so as to define a PN junction at the interface between the upper portion and a central portion of the semiconductor gate layer.

### CROSS-REFERENCE TO RELATED APPLICATION(S)

This application claims the priority benefit of French patent application number 2301105, filed on Feb. 6, 2023, entitled “Transistor HEMT” which is hereby incorporated by reference to the maximum extent allowable by law.

### BACKGROUND

### Technical Field

The present disclosure generally concerns the field of transistors and more particularly the field of high electron mobility transistors also called HEMTs.

### Description of the Related Art

HEMT transistors rely on a heterojunction having a two-dimensional electron gas also called 2DEG forming at its surface.

There exists a use for improving HEMT transistors and their manufacturing methods.

### BRIEF SUMMARY

To achieve this, an embodiment provides a method of forming an HEMT transistor, comprising the following successive steps:
a) providing a stack comprising a semiconductor channel layer, a semiconductor barrier layer on top of and in contact with the semiconductor channel layer, and a semiconductor gate layer arranged on top of and in contact with the semiconductor barrier layer, the semiconductor gate layer comprising P-type dopant elements; and
b) compensating for the P-type doping with oxygen atoms, in an upper portion of the semiconductor gate layer, by an oxygen anneal, so as to define a PN junction at the interface between the upper portion and a central portion of the semiconductor gate layer.

According to an embodiment, the method comprises a step c) of etching of the semiconductor gate layer.

According to an embodiment, the etching of step c) is performed after step b).

According to an embodiment:

the etching of step c) is partial, a portion of the thickness of the semiconductor gate layer remaining at the end of the etch step; and the etching of step c) is followed by another step of compensation for the P-type doping with oxygen atoms in a peripheral portion of the etched semiconductor layer and by another etch step enabling the removal of what remains of the semiconductor gate layer at the end of the etch step of step c).

An other embodiment provides a HEMT transistor comprising:
a semiconductor channel layer;
a semiconductor barrier layer on top of and in contact with the semiconductor channel layer; and
a semiconductor gate arranged on top of and in contact with a first surface of the semiconductor barrier layer, opposite to the semiconductor channel layer,
   wherein the gate comprises an upper portion and a central portion, the upper portion and the central portion comprising P-type dopant elements, and the upper portion comprising oxygen atoms compensating for the P-type doping so as to define a PN junction at the interface between the central portion and the upper portion.

According to an embodiment, the gate comprises a peripheral portion comprising P-type dopant elements and comprising oxygen atoms compensating for the P-type doping.

According to an embodiment, the transistor comprises a passivation layer extending on a first surface of the first semiconductor layer and the sides of the gate and a peripheral portion of a surface of the gate opposite to the first semiconductor layer.

According to an embodiment, the first passivation layer is made of alumina.

According to an embodiment, the first semiconductor layer is based on gallium nitride.

According to an embodiment, the first semiconductor layer is made of aluminum-gallium nitride.

According to an embodiment, the first semiconductor layer comprises an aluminum content decreasing from its first surface.

According to an embodiment, the transistor comprises a second semiconductor layer in contact with a second surface of the first semiconductor layer, opposite to the first surface.

According to an embodiment, the second semiconductor layer is made of gallium nitride.

According to an embodiment, the semiconductor gate is made of gallium nitride.

Another embodiment provides a power conversion or matching circuit comprising at least one transistor as described.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1 is a partial and simplified cross-section view of an example of an HEMT transistor;

FIG. 2 is a partial and simplified cross-section view of an HEMT transistor according to a first embodiment;

FIG. 3A, FIG. 3B, FIG. 3C, FIG. 3D, FIG. 3E, and FIG. 3F are cross-section views illustrating steps of an example of a method of manufacturing the HEMT transistor illustrated in FIG. 2;

FIG. 4 is partial and simplified cross-section view of an HEMT transistor according to a second embodiment; and

FIG. 5 is a partial and simplified cross-section view of an HEMT transistor according to a third embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the applications that the described HEMT transistors may have, are not detailed, the embodiments being compatible with usual applications of HEMT transistors. The field of HEMT transistors, capable of withstanding relatively high voltages in the off state, for example, voltages in the order of from 100 to 650 volts, is more particularly considered herein. The described transistors can, for example, be used in various power conversion or matching circuits, such as in industrial equipment, display or lighting devices, telecommunications equipment, automotive device, etc.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front,” “back,” “top,” “bottom,” “left,” “right,” etc., or to relative positional qualifiers, such as the terms “above,” “below,” “upper,” “lower,” etc., or to qualifiers of orientation, such as “horizontal,” “vertical,” etc., reference is made, unless specified otherwise, to the orientation of the figures.

Unless specified otherwise, the expressions “around,”, “approximately,” “substantially” and “in the order of” signify within 10%, and preferably within 5%.

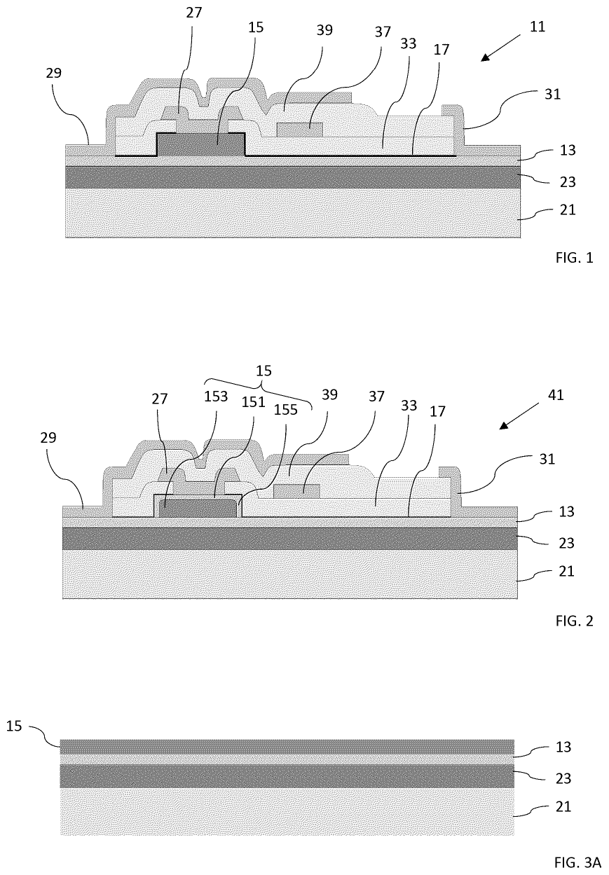

FIG. 1 is a partial and simplified cross-section view of an example of an HEMT transistor 11.

HEMT transistor 11 comprises a first semiconductor layer 13 called barrier layer, arranged on a second conductive layer 23 called channel layer. Semiconductor layer 13 is for example in contact, by its lower surface, with the upper surface of conductive layer 23. As an example, the stack comprising semiconductor layer 13 and semiconductor layer 23 rests on a substrate 21. Semiconductor layer 23 is for example in contact, by its lower surface, with the upper surface of substrate 21. The interface between semiconductor layer 13 and semiconductor layer 23 defines a heterojunction at the surface of which a two-dimension electron gas 2DEG also called electron channel is formed.

Semiconductor layers 13 and 23 are for example made of semiconductor materials of III-V type, for example, based on gallium nitride (GaN). Semiconductor layer 13 is for example made of aluminum-gallium nitride (AlGaN). Semiconductor layer 13 is for example made of gallium nitride (GaN).

As an example, substrate 21 is made of a semiconductor material. Substrate 21 is for example made of silicon, or of silicon carbide. As a variant, substrate 21 is made of aluminum nitride. Substrate 21 for example comprises, on its upper surface side, a buffer layer, not detailed in the drawings, for example, made of gallium nitride. The buffer layer is for example in contact, by its upper surface, with the lower surface of semiconductor layer 23.

HEMT transistor 11 comprises a gate 15 on the upper surface of semiconductor layer 13. Gate 15 is for example in contact, by its lower surface, with the upper surface of semiconductor layer 13.

Gate 15 is for example made of a semiconductor material, for example, of a III-V type semiconductor material, for example, of gallium nitride. Gate 15 comprises P-type dopant elements, for example, magnesium atoms. As an example, gate 15 has a thickness in the range from 20 nm to 200 nm, for example, in the range from 80 nm to 120 nm, for example in the order of 100 nm.

As an example, HEMT transistor 11 further comprises a source contact metallization 29 and a drain contact metallization 31. As an example, contact metallizations 29 and 31 are based on titanium, titanium nitride, and/or on an alloy of aluminum and of copper. Source and drain contact metallizations 29 and 31 for example each define an ohmic contact with semiconductor layer 13. Contact metallizations 29 and 31 are for example located on top of and in contact with semiconductor layer 13, on either side of gate 15.

HEMT transistor 11 further comprises a passivation layer 17 covering the sides of the gate, a portion of the upper surface of gate 15, and extending over a portion of the upper surface of semiconductor layer 13 not covered with gate 15. As an example, passivation layer 17 is in contact, by its lower surface, with the upper surface of semiconductor layer 13. Passivation layer 17 is for example further in contact with the sides of gate 15. In the embodiment of FIG. 1, passivation layer 17 extends laterally between source and drain contact metallizations 29 and 31.

Passivation layer 17 for example has a thickness in the range from 2 nm to 20 nm, for example in the range from 2 nm to 10 nm, for example, in the order of 5 nm. Passivation layer 17 is for example made of a dielectric material, for example, of alumina (Al₂O₃), of silicon dioxide (SiO₂), of silicon nitride (Si₃N₄), of aluminum nitride (AlN), or of hafnium oxide (HfO₂).

Gate 15 is for example topped with a gate contact metallization 27.

As an example, gate contact metallization 27 is in contact, by its lower surface, with the upper surface of gate 15. Gate contact metallization 27 then extends through layer 17, which only covers the upper surface of gate 15 on its periphery.

As an example, gate contact metallization 27 is based on titanium nitride and/or on titanium, and/or on tantalum, and/or an alloy of tungsten and tantalum, and/or an alloy of tungsten and titanium, and/or on an alloy of aluminum and copper.

In this example, metallization 27 defines a Schottky contact with semiconductor gate 15. Semiconductor gate 15 and metallization 27 define a Schottky diode having its anode corresponding to semiconductor gate 15 and having its cathode corresponding to metallization 27.

HEMT transistor 11 for example comprises a plurality of levels of insulating layers inside and for example on top of which are formed metallizations.

As an example, HEMT transistor 11 comprises an insulating layer 33 on top of and in contact with the upper surface of passivation layer 17. As an example, insulating layer 33 covers the entire surface of passivation layer 17. Insulating layer 33 is for example opened in front of a central portion of gate 15 to be crossed by gate contact metallization 27. Insulating layer 33 is for example made of a dielectric material, for example, of an oxide, for example, of silicon dioxide (SiO₂) or of silicon nitride (Si₃N₄).

As an example, HEMT transistor 11 comprises a metal region 37 extending over a portion of the surface of insulating layer 33. As an example, metal region 37 is based on titanium nitride and/or on titanium, and/or on tantalum, and/or an alloy of tungsten and tantalum, and/or an alloy of tungsten and titanium, and/or on an alloy of aluminum and copper. Metal region 37 is for example made of the same material as gate contact metallization 27.

HEMT transistor 11 may comprise a second insulating layer 39 covering the entire structure except for source and drain contact metallizations 29 and 31. Second insulating layer 39 is, for example, made of the same material as insulating layer 33.

Metal region 37 for example has the function of modifying the profile of the distribution of the electric field of the edge of the gate, located on the side of the drain (the right-hand side of the gate in FIG. 1), and thus of decreasing the peak of the critical electric field, thus increasing the avalanche voltage. Metal region 37 is for example called a field plate.

As an example, source contact metallization 29 further extends on the upper surface of insulating layer 39 towards drain contact metallization 31, without reaching drain contact metallization 31.

In the transistor of FIG. 1, channel 2DEG is for example normally off, that is, it is interrupted under gate 15, which prevents the flowing of a current between the source and the drain of the transistor. The transistor is said to be in the off state. The channel may be restored (that is, made conductive) by the biasing of gate 15. In this case, a current may establish between the source and the drain of the transistor. The described embodiments may also apply to normally-on transistors.

The presence of passivation layer 17 allows the protection of the upper surface of semiconductor layer 13 on which dangling bonds may be present and likely to generate leakage currents and/or a decrease in the breakdown voltage of the transistor. Passivation layer 17 fills these bonds to make the surface of semiconductor layer 13 electrically inactive.

Passivation layer 17 also enables to protect semiconductor layer 13 against oxidation and to improve its surface condition to which the 2DEG channel is sensitive.

While passivation layer 17 plays an important role in the quality and lifetime of the transistor, its presence may cause the accumulation of electrons along the sides of gate 15, under passivation layer 17. This phenomenon is for example enhanced by the damaging of the sides of the gate cause by the etching of gate 15. This results in the occurrence of leakage currents between gate contact metallization 27 and source and/or drain metallizations 29 and/or 31, running through the gate sides.

To decrease this phenomenon, it is provided to modify the doping of an upper portion of semiconductor gate 15, to obtain an N-type doping in this upper portion, and thus define a PN junction between this upper portion and a lower portion of the gate. Contact metallization 27 then forms an ohmic contact with the upper N-type portion of semiconductor gate 15. Thus, the Schottky diode formed, in the example of FIG. 1, between semiconductor gate 15 and metallization 27, is replaced with a PN diode formed between the lower portion and the upper portion of semiconductor gate 15.

FIG. 2 is a partial and simplified cross-section view of an HEMT transistor 41 according to a first embodiment.

More particularly, FIG. 2 illustrates an HEMT transistor 41 similar to the transistor 11 illustrated in FIG. 1 with the difference that the gate 15 of transistor 41 comprises, in an upper portion 151 and in a peripheral portion 155 of the gate, oxygen atoms compensating for the P-type doping so as to obtain an N-type doping and thus define a PN junction at the interface between a central portion 153 and the upper and peripheral portions 151 and 155 of the gate.

As an example, upper N-type portion 151 has a thickness in the range from 10 nm to 100 nm, for example in the range from 30 nm to 70 nm, for example, in the order of 50nm. As an example, peripheral N-type portion 155 has a thickness in the range from 10 nm to 100 nm, for example in the range from 30 nm to 70 nm, for example in the order of 50 nm.

As an example, gate 15 is made of aluminum-gallium nitride. As an example, gate 15 is made of aluminum-gallium nitride having its chemical formula corresponding to AlₓGaₓ₋₁ N, where x is a positive integer. Gate 15 comprises P-type dopant elements, for example, magnesium atoms.

As an example, semiconductor layer 13 comprises a non-homogeneous aluminum content across its general thickness. Layer 13 has, for example, an aluminum content increasing from its lower surface, that is, it has an aluminum content in the vicinity of gate 15 greater than that in the vicinity of semiconductor layer 23.

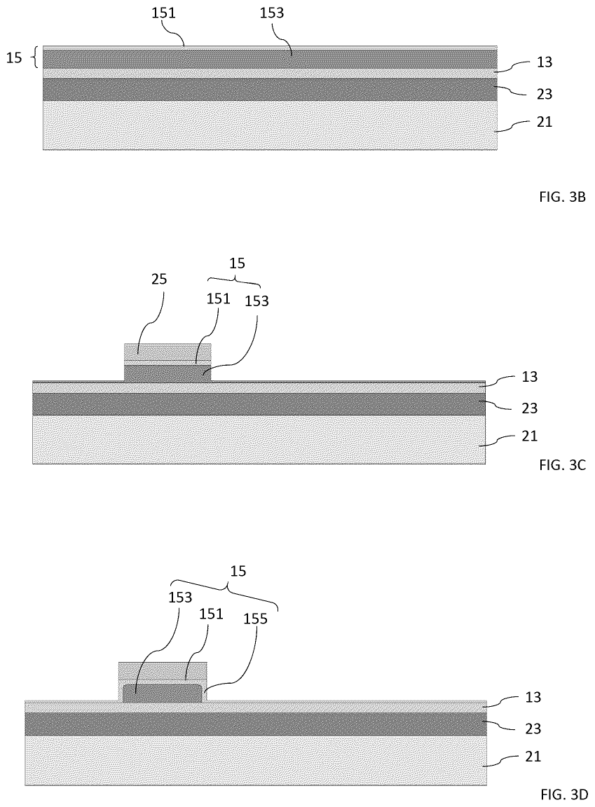

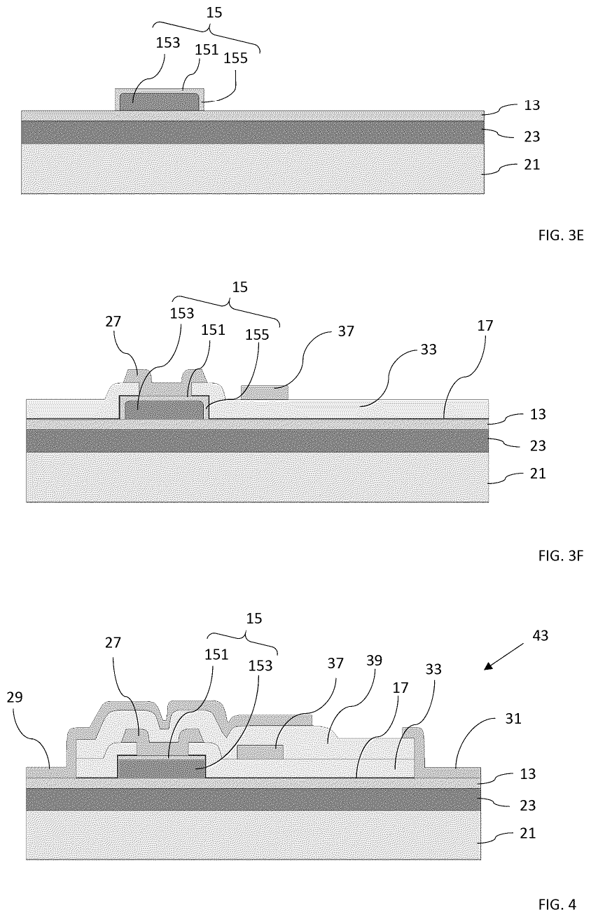

FIG. 3A, FIG. 3B, FIG. 3C, FIG. 3D, FIG. 3E, and FIG. 3F are cross-section views illustrating steps of an example of a method of manufacturing the HEMT transistor 41 illustrated in FIG. 2.

FIG. 3A illustrates an initial structure comprising, in the order, from the lower surface of the structure, substrate 21, second semiconductor layer 23, and first semiconductor layer 13. The initial structure further comprises a gate layer 15 where the gate 15 of transistor 41 will be formed. In the initial structure illustrated in FIG. 3A, layers 23, 13, and 15 each continuously extend with a substantially uniform thickness over the entire upper surface of substrate 21.

As an example, gate layer 15 is formed on the upper surface of layer 13, by a vapor deposition method, for example, an epitaxy method in metal organic vapor phase also called metal organic chemical vapor deposition or MOCVD method. As an example, the deposition of gate 15 is performed under an at least partial vacuum. Gate layer 15 is for example doped during its deposition. As a variant, gate layer 15 is doped after its deposition by a dopant implantation step. In this example, gate layer 15 is P-type doped, for example, with magnesium atoms.

FIG. 3B illustrates a structure obtained at the end of a first step of compensation for the doping of gate layer 15 with oxygen atoms, in an upper portion of the gate layer 15.

More particularly, during this step, an oxygen anneal, and for example under nitrogen, of the structure illustrated in FIG. 3A is performed so that the P-type doping of an upper portion of gate layer 15 is compensated for with oxygen atoms. The upper portion of gate layer 15 then changes doping type, it is then spoken of a doping compensation. Here, an upper portion of gate layer 15 passes from a P-type doping to an N-type doping.

In practice, the oxygen anneal enables, for example under dinitrogen, in a first phase, to unbind hydrogen atoms bound to the dopant elements present in the gate layer, for example, magnesium atoms. In a second phase, the oxygen anneal allows the implantation of oxygen atoms, and for example under dinitrogen, which are N-type dopant elements, in the structure and more particularly in the upper portion of gate layer 15.

As an example, the oxygen anneal comprises an oxygen content in the range from 1% to 20%, for example in the range from 2% to 10%, for example, in the order of 5%. The oxygen anneal is for example performed at a temperature in the range from 600° C. to 1,000° C., for example in the range from 750° C. to 900° C., for example in the order of 820° C.

At the end of this step, gate layer 15 comprises an upper portion 151 and a central portion 153 having their interface defining a PN junction.

FIG. 3C illustrates a structure obtained at the end of a first step of etching of gate layer 15.

More particularly, during this step, there is in a first step formed a masking layer 25 on top of and, for example, in contact with the structure illustrated in FIG. 3B. Masking layer 25 is for example made of a material resistant to the etching described hereafter, for example, made of an oxide, for example, of tetraethyl orthosilicate or TEOS. As an example, masking layer 25 is not made of a resin. Masking layer 25 for example has a thickness in the range from 50 nm to 200 nm, for example, in the order of 100 nm. As an example, masking layer 25 is formed so that it covers the structure illustrated in FIG. 3B at the location of the future gate 15.

During this step, there is in a second phase etched gate layer 15 through masking layer 25 for example by a plasma etching method, for example by a chlorine-based plasma etching method, for example, by a boron trichloride (BCl₃) and chlorine (Cl₂) plasma etching.

Gate layer 15 and more precisely the portion of gate layer 15 located outside of the location in front of masking layer 25 is, during this step, partially etched, that is, it is etched across a portion only of its thickness. As an example, during this step, gate layer 15 is etched across from 50% to 90% of its thickness, for example across 80% of its thickness.

At the end of this step, gate layer 15 remains in front of masking layer 25 and outside of the location in front of masking layer 25 only across a portion of its thickness.

FIG. 3D illustrates a structure obtained at the end of a second step of compensation for the doping of gate layer 15 with oxygen atoms.

More particularly, during this step, an oxygen anneal of the structure illustrated in FIG. 3C is performed similarly to what has been described in relation with FIG. 3B. This step is for example carried out while masking layer 25 is still present at the surface of the structure. The sides of the portion of gate layer 15 located under masking layer 25 and an upper portion of what remains of gate layer 15 outside of the location in front of masking layer 25 are then compensated for with oxygen atoms.

At the end of this step, gate layer 15 comprises an N-type doped upper portion 151 and peripheral portion 155 and P-type doped central portion 153. As an example, the peripheral portion 155 of gate layer 15 has a thickness in the range from 10 to 100 nm, for example, in the range from 30 nm to 70 nm, for example, in the order of 50 nm.

Letting a portion of gate layer 15 remain outside of the location in front of masking layer 25 enables, during this step, to protect semiconductor layer 13 and to compensate for the doping of gate layer 15 without modifying the doping of semiconductor layer 13.

FIG. 3E illustrates a structure obtained at the end of a second step of etching of gate layer 15 through masking layer 25 to form gate 15.

During this step, what remains of gate layer 15 outside of the location in front of masking layer 25 is for example etched, for example by a plasma etching method, for example, by a plasma etching method based on chlorine, for example, by a plasma etching method based on chlorine (Cl₂) and oxygen (O₂) or by a plasma etching method based on boron trichloride (BCl₃) and sulfur hexafluoride (SF₆).

As an example, the etch step is carried on until the upper surface of semiconductor layer 13 is exposed and gate layer 15 only remains in front of masking layer to form the gate 15 of the transistor.

This etch step is for example followed by a step of removal of masking layer 25. As an example, the removal of the etch mask is performed by means of hydrogen fluoride (HF).

FIG. 3F illustrates a structure obtained at the end of a step of forming of passivation layer 17, of insulating layer 33, of metallization 27, and of region 37 on the upper surface of the structure illustrated in FIG. 3E.

During this step, in a first phase, passivation layer 17 is formed in full wafer fashion, so that it covers the entire upper surface of the structure illustrated in FIG. 3E.

Passivation layer 17 is for example formed in contact with the upper surface of semiconductor layer 13 and the sides and the upper surface of gate 15. Passivation layer 17 is for example formed by a method of thin layer deposition, for example, by ALD. As an example, the method of deposition of passivation layer 17 is plasma or thermal-enhanced. As an example, passivation layer 17 has a thickness in the range from 1 nm to 10 nm, for example in the range from 3 nm to 7 nm, for example, in the order of 5 nm.

In a second phase, during this step, insulating layer 33 is formed in full wafer fashion, so that it covers the entire upper surface of passivation layer 17. Insulating layer 33 is for example formed in contact with passivation layer 17. Insulating layer 33 is for example formed by a plasma-enhanced chemical vapor deposition or PECVD. At the end of this step, insulating layer 33 has a thickness for example in the range from 150 nm to 400 nm, for example in the range from 200 nm to 350 nm, for example, in the order of 300 nm.

As an example, the steps of deposition of passivation layer 17 and of insulating layer 33 are preceded by one or a plurality of steps of preparation of the surface of the structure illustrated in FIG. 3E. The preparation of the surface of the structure illustrated in FIG. 3E may comprise a cleaning for example consisting of a chemical cleaning by means of acid, for example, hydrogen chloride (HCl) or hydrogen fluoride (HF). The preparation of the surface of the structure illustrated in FIG. 3E may further comprise a cleaning for example consisting of a surface oxidation.

Passivation layer 17 will thus be formed in contact with an oxide film, itself formed in contact with the upper surface of layer 13.

During this step, in a third phase, passivation layer 17 and insulating layer 33 are removed in front of a central portion of the upper surface of gate 15 and gate contact metallization 27 is formed in the formed opening. As an example, this step comprises the removal of layer 33 and then the removal of layer 17. As an example, the removal of layer 33 is performed by plasma etching, for example, based on fluorine, for example, based on carbon tetrafluoride (CF₄). As an example, the removal of layer 17 is performed by plasma etching, for example, based on chlorine, for example, based on boron trichloride (BCl₃). In this example, layer 17 is etched to expose the upper surface of gate 15.

The above-mentioned etchings are for example followed by a step of cleaning of the upper surface of the structure to remove, for example, residues originating from masking layer 25 and impurities originating from the etching of gate layer 15. The cleaning of the structure for example comprises a step of stripping by oxygen and nitrogen (N₂) plasma. The cleaning of the structure may further comprise a step of removal of organic residues by means of a solvent.

During this step, there is for example formed gate contact metallization 27 in the opening formed in layers 17 and 33 in front of the central portion of gate 15. As an example, gate contact metallization 27 is formed on top of and in contact with the upper surface of gate 15 and more precisely on top of and in contact with the upper portion 151 of gate 15.

As an example, during this step, region 37 is further formed on a portion of the surface of first insulating layer 33. Gate contact metallization 27 and region 37 are for example formed by deposition of one or a plurality of layers made of a metallic material followed by an etch step.

As an example, the step of forming of gate contact metallization 27 and of region 37 is preceded by a step of preparation of the surface of the structure, for example consisting of a chemical cleaning by means of acid, for example, hydrogen chloride (HCl).

At the end of this step, insulating layer 39 is for example formed on the upper surface of the structure illustrated in FIG. 3F. During this step, insulating layer 39 is for example formed in full wafer fashion, so that it covers the entire upper surface of the structure illustrated in FIG. 3F, that is, the upper surface and the sides of gate contact metallization 27 and of region 37 and a portion of layer 33. Insulating layer 39 is for example formed by a method identical to the method of forming layer 33 described in relation with FIG. 3F. At the end of this step, insulating layer 39 has a thickness for example in the range from 150 nm to 400 nm, for example in the range from 200 nm to 350 nm, for example, in the order of 300 nm.

Eventually, the ohmic contacts and more particularly source and drain contact metallizations 29 and 31 are for example formed to form the structure illustrated in FIG. 2.

For this purpose, openings intended to receive source and drain contact metallizations 29 and 31 are, first, created in layers 17, 33, and 39. The openings are for example formed by a plasma etching method, for example, based on fluorine, for example, based on carbon tetrafluoride (CF₄). The above-mentioned etching is for example selective and does not etch gallium nitride semiconductor layer 13. The etching of layers 17, 33, and 39 thus stops when the upper surface of layer 13 is exposed. The step of forming of the openings intended to receive contact metallizations 29 and 31 is for example followed by a step of cleaning of the upper surface of the structure, for example similarly to what has been described hereabove for gate contact metallization 27 and region 37. As an example, a step of surface preparation of the upper surface of layer 13 in the openings, to accommodate contact metallizations 29 and 31, may be provided. This step for example comprises a chemical cleaning by means of acid, for example hydrogen chloride (HCl).

In a second phase, source and drain contact metallizations 29 and 31 are for example formed in the previously-formed openings. Metallizations 29, 31 and a region 47 are for example formed by deposition of one or a plurality of layers made of a metallic material over the entire upper surface of the structure, here the upper surface of layers 13 and 39, followed by an etch step.

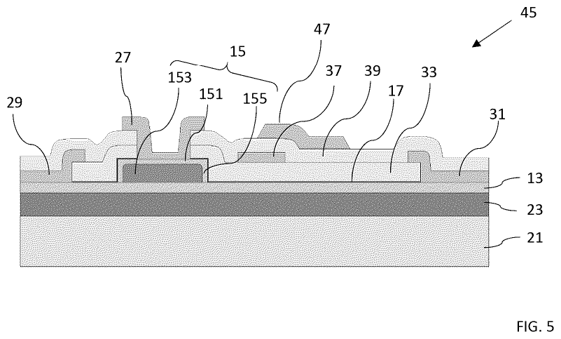

FIG. 4 is a partial and simplified cross-section view of an HEMT transistor 43 according to a second embodiment.

The transistor 43 illustrated in FIG. 4 is similar to the HEMT transistor 41 illustrated in FIG. 2 with the difference that the peripheral portions of gate 15 are not N-type doped. The method of manufacturing transistor 43 differs from the method of manufacturing transistor 41 in that, in the method of manufacturing transistor 43, the second compensation step is omitted. Further, the transistor 43 illustrated in FIG. 4 is similar to the HEMT transistor 41 illustrated in FIG. 2 with the difference that the etch step described in relation with FIG. 3C is a complete etching and the step of continuation of the etching of gate layer 15 is omitted.

Thus, in the method of manufacturing transistor 43, the etching of gate layer 15 is performed in a single step, that is, gate layer 15 is removed from the location in front of masking layer 25 across its entire thickness during a single etch step. The method of manufacturing transistor 43 comprises, at the end of the step of etching of gate layer 15 to form gate 15, the step of forming of layers 17 and 33 similarly to what has been described in relation with FIG. 3F.

More particularly, in this example, transistor 43 is different from transistor 41 in that gate 15 comprises no N-type doped peripheral portions 155.

FIG. 5 is a partial and simplified cross-section view of an HEMT transistor 45 according to a third embodiment.

The transistor 45 illustrated in FIG. 5 is similar to the HEMT transistor 41 illustrated in FIG. 2 with the difference that, in the method of manufacturing transistor 45, source and drain contact metallizations 29 and 31 have been formed before the forming of gate contact metallization 27 while in the method of manufacturing transistor 41, source and drain contact metallizations 29 and 31 have been formed after the forming of gate contact metallization 27.

More particularly, in this example, transistor 45 is different from transistor 41 in that gate contact metallization 27 crosses layer 39 and in that layer 39 covers contact metallizations 29 and 31.

Various embodiments and variants have been described. Those skilled in the art will understand that certain features of these various embodiments and variants may be combined, and other variants will occur to those skilled in the art. In particular, the second and third embodiments previously described respectively in FIGS. 4 and 5 may be combined.

Further, although an example of embodiment where the transistor gate 15 is in contact with the upper surface of upper semiconductor layer 13 has been described hereabove, as a variant, gate 15 may be separated from semiconductor layer 13 by a gate insulator layer.

Further, the embodiments are not limited to the examples of numerical values nor to the examples of materials mentioned in the present disclosure.

Finally, the practical implementation of the described embodiments and variations is within the abilities of those skilled in the art based on the functional indications given hereabove.

A method of forming an HEMT transistor (41), may be summarized as including the following successive steps: a) providing a stack including a semiconductor channel layer (23), a semiconductor barrier layer (13) on top of and in contact with the semiconductor channel layer (23), and a semiconductor gate layer (15) arranged on top of and in contact with the semiconductor barrier layer (13), the semiconductor gate layer (15) including P-type dopant elements; and b) compensating for the P-type doping with oxygen atoms, in an upper portion (151) of the semiconductor gate layer (15), by an oxygen anneal, so as to define a PN junction at the interface between the upper portion (151) and a central portion (153) of the semiconductor gate layer (15).

The method may include a step c) of etching of the semiconductor gate layer (15).

The etching of step c) may be performed after step b).

The etching of step c) may be partial, a portion of the thickness of the semiconductor gate layer (15) remaining at the end of the etch step; and the etching of step c) may be followed by another step of compensation for the P-type doping with oxygen atoms in a peripheral portion of the etched semiconductor layer (15) and by another etch step enabling the removal of what remains of the semiconductor gate layer (15) at the end of the etch step of step c).

The HEMT transistor (11) may be summarized as including: a semiconductor channel layer (23); a semiconductor barrier layer (13) on top of and in contact with the semiconductor channel layer (23); and a semiconductor gate (15) arranged on top of and in contact with a first surface of the semiconductor barrier layer (13), opposite to the semiconductor channel layer (23), wherein the gate (15) includes an upper portion (151) and a central portion (153), the upper portion (151) and the central portion (153) including P-type dopant elements, and the upper portion (151) including oxygen atoms compensating for the P-type doping so as to define a PN junction at the interface between the central portion (153) and the upper portion (151).

The gate (15) may include a peripheral portion (155) including P-type dopant elements and including oxygen atoms compensating for the P-type doping.

The transistor may include a passivation layer (17) extending on a first surface of the first semiconductor layer (13) and the sides of the gate (15) and a peripheral portion of a surface of the gate (15) opposite to the first semiconductor layer (13).

The first passivation layer (17) may be made of alumina.

The first semiconductor layer (13) may be based on gallium nitride.

The first semiconductor layer (13) may be made of aluminum-gallium nitride.

The first semiconductor layer may include an aluminum content decreasing from its first surface.

The transistor may include a second semiconductor layer (23) in contact with a second surface of the first semiconductor layer (13), opposite to the first surface.

The second semiconductor layer (23) may be made of gallium nitride.

The semiconductor gate (15) may be made of gallium nitride.

The power conversion or matching circuit may be summarized as including at least one transistor.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of forming an HEMT transistor, comprising:
forming a stack comprising a semiconductor channel layer, a semiconductor barrier layer on top of and in contact with the semiconductor channel layer, and a semiconductor gate layer on top of and in contact with the semiconductor barrier layer, the semiconductor gate layer comprising P-type dopant elements; and
compensating for the P-type doping with oxygen atoms, in an upper portion of the semiconductor gate layer, by performing a first oxygen anneal, creating a PN junction at the interface between the upper portion and a central portion of the semiconductor gate layer.

2. The method according to claim 1, comprising a first etching of the semiconductor gate layer.

3. The method according to claim 2, wherein the first etching is performed after the performing the first oxygen anneal.

4. The method according to claim 3, wherein:
the first etching of the semiconductor gate layer is partial, a portion of the thickness of the semiconductor gate layer remaining at the end of the first etching; and
the first etching of the semiconductor gate layer is followed by a second oxygen anneal compensating for the P-type doping with oxygen atoms in a peripheral portion of the etched semiconductor layer and by a second etching enabling the removal of what remains of the semiconductor gate layer at the end of the first etching.

5. An HEMT transistor comprising:
a semiconductor channel layer;
a semiconductor barrier layer on top of and in contact with the semiconductor channel layer; and
a semiconductor gate arranged on top of and in contact with a first surface of the semiconductor barrier layer, opposite to the semiconductor channel layer,
wherein the gate comprises an upper portion and a central portion, the upper portion and the central portion comprising P-type dopant elements, and the upper portion comprising oxygen atoms forming a PN junction at the interface between the central portion and the upper portion.

6. The HEMT transistor according to claim 5, wherein the gate comprises a peripheral portion comprising P-type dopant elements and comprising oxygen atoms compensating for the P-type doping.

7. The HEMT transistor according to claim 5, comprising a passivation layer extending on the first surface of the semiconductor barrier layer and the sides of the gate and a peripheral portion of a surface of the gate opposite to the semiconductor barrier layer.

8. The HEMT transistor according to claim 7, wherein the passivation layer is made of alumina.

9. The HEMT transistor according to claim 5, wherein the semiconductor barrier layer includes gallium nitride.

10. The HEMT transistor according to claim 9, wherein the semiconductor barrier layer is made of aluminum-gallium nitride.

11. The HEMT transistor according to claim 10, wherein the first surface of the semiconductor barrier layer comprises a first aluminum content greater than a second aluminum content of a second surface of the semiconductor barrier layer opposite the first surface.

12. The HEMT transistor according to claim 5, comprising a second semiconductor layer in contact with a second surface of the semiconductor barrier layer, opposite to the first surface.

13. The HEMT transistor according to claim 12, wherein the second semiconductor layer is made of gallium nitride.

14. The HEMT transistor according to claim 5, wherein the semiconductor gate is made of gallium nitride.

15. A device comprising:
a conductive layer;
a semiconductor layer having a first surface in contact with the conductive layer and a second surface opposite the first surface of the semiconductor layer; and
a gate having a first surface coupled to the second surface of the semiconductor layer, a second surface opposite the first surface of the gate, and a first sidewall transverse to the first and second surfaces of the gate, the gate including:
a central portion with a first conductivity type;
an outer layer with a second conductivity type opposite the first conductivity type at the second surface of the gate; and
a peripheral layer with the second conductivity type at the first sidewall of the gate.

16. The device according to claim 15, wherein the gate has a P-type doping and the outer and peripheral layers have an N-type doping.

17. The device according to claim 15, comprising a PN junction at an interface between the central portion of the gate and the peripheral and outer layers of the gate.

18. The device according to claim 15, comprising a passivation layer on the second surface of the semiconductor layer, the peripheral layer of the gate, and the outer layer of the gate.

19. The device according to claim 18, comprising a gap in the passivation layer on the outer layer of the gate and a gate contact metallization directly coupled to the gate through the gap.

20. The device according to claim 19, comprising an insulating layer entirely covering the passivation layer and including a portion between the gate contact metallization and the outer layer of the gate.
